(19) United States
(12) Patent Application Publication
(10) Pub. No.: US 2013/0219713 A1
(43) Pub. Date: Aug. 29, 2013

(54) METHOD OF MANUFACTURING A LAMINATE CIRCUIT BOARD WITH A MULTILAYER CIRCUIT STRUCTURE

(71) Applicant: KINSUS INTERCONNECT TECHNOLOGY CORP., (US)

(72) Inventors: Jun-Chung Hsu, Taoyuan County (TW); Chi-Ming Lin, Taipei (TW); Tso-Hung Yeh, New Taipei City (TW); Ya-Hsiang Chen, Yunlin County (TW)

(73) Assignee: KINSUS INTERCONNECT TECHNOLOGY CORP., Taoyuan (TW)

(21) Appl. No.: 13/663,663

(22) Filed: Oct. 30, 2012

(30) Foreign Application Priority Data
Feb. 23, 2012 (TW) 101106103

(51) Int. Cl. H05K 3/46

(52) U.S. Cl. 29/846

(57) ABSTRACT

A method of manufacturing a laminate circuit board with a multilayer circuit structure which includes the steps of forming a metal layer on a substrate, patterning the metal layer to form a circuit metal layer, forming a nanometer plating layer on the circuit metal layer, forming a cover layer to cover the substrate and the nanometer plating layer, forming through holes in the cover layer to generate openings exposing part of the nanometer plating layer, and finally forming a second metal layer on the cover layer to fill up the openings is disclosed. The nanometer plating layer is used to obtain same effect of previously roughening by chemical bonding, such that no circuit width is reserved for compensation, and the density of the circuit increases such that much more dense circuit can be implemented.

### CROSS-REFERENCE TO RELATED APPLICATION

This application claims the priority of Taiwanese patent application No. 101106103, filed on Feb. 23, 2012, which is incorporated herewith by reference.

### BACKGROUND OF THE INVENTION

1. Field of the Invention

The present invention generally relates to a method of manufacturing a laminate circuit board with a multilayer circuit structure, and more specifically to forming a nanometer plating layer over a circuit metal layer formed on the up and down sides of a substrate.

2. The Prior Art

Please refer to FIG. 1. The traditional laminate circuit board generally comprises a substrate 10, a circuit metal layer 22 and a cover layer 30, as shown in FIG. 1. The substrate 10 has a rough upper surface 15, and the circuit metal layer 22 is formed on the upper surface 15 and usually made of at least one of copper, aluminum, silver and gold. The cover layer 30 made of a binder or a solder resist is formed to cover the circuit metal layer 22. Since the circuit metal layer 22 and cover layer 30 are made of different materials, the outer surface 25 of the circuit metal layer 22 needs to be previously roughened by chemical, mechanical or plasma treatment to increase the surface friction coefficient and avoid peeling off. Thus, the junction property is improved by the outer surface 25 previously roughened.

However, one of the shortcomings of the circuit metal layer 22 with the roughened surface in the prior arts is that the design of the circuit on the circuit metal layer is extremely constrained as the circuit becomes much denser because it is necessary to reserve sufficient circuit width to compensate the loss due to the roughening process of the circuit metal layer. Therefore, it needs a method of manufacturing a laminate circuit board with a multi-layer circuit structure without compensation for circuit width so as to increase the density of the circuit.

### SUMMARY OF THE INVENTION

A primary objective of the present invention is to provide a method of manufacturing a laminate circuit board with a multilayer circuit structure. The method comprises: forming the metal layer on both the up side and the down side of the substrate; patterning the metal layer to form the circuit metal layer through the image transfer process; forming the nanometer plating layer with a thickness of 5˜40 nm on the circuit metal layer; and forming the cover layer made of the binder or the solder resist on the substrate for covering the circuit metal layer and the nanometer plating layer to generate the laminate circuit board, wherein at least one of the up side and the down side of the substrate is a smooth surface, and the outer surface of the circuit metal layer, the smooth surface of the substrate and the outer surface of the nanometer plating layer have a roughness which is defined by Ra (Arithmetical mean roughness)<0.35 μm and Rz (Ten-point mean roughness)<3 μm and not recognizable by cross-sectional examination through an optical microscope of 1,000 magnifications.

Another objective of the present invention is to provide a method of manufacturing the laminate circuit board with the multilayer circuit structure. The method comprises the steps of: forming the metal layer on at least one surface of the substrate, the at least one surface of the substrate being a smooth surface; patterning the metal layer to form the circuit metal layer through the image transfer process; forming the nanometer plating layer with a thickness of 5˜40 nm on the circuit metal layer; forming the cover layer made of the binder or the solder resist on the substrate for covering the circuit metal layer and the nanometer plating layer; forming at least one through hole on the cover layer with respect to the circuit metal layer to generate at least one opening exposing part of the nanometer plating layer; forming the second metal layer on the cover layer to at least fill up the at least one opening; and repeating the above steps to generate the laminate circuit board, wherein the outer surface of the circuit metal layer, the smooth surface of the substrate and the outer surface of the nanometer plating layer have a roughness which is defined by Ra<0.35 μm and Rz<3 μm and not recognizable by cross-sectional examination through an optical microscope of 1,000 magnifications.

A yet objective of the present invention is to provide a method of manufacturing the laminate circuit board with the multilayer circuit structure. The method comprises: forming the metal layer on the performing substrate; patterning the metal layer to form the circuit metal layer through the image transfer process; forming the nanometer plating layer with a thickness of 5˜40 nm on the circuit metal layer; pressing the performing substrate against the substrate to push the circuit metal layer and the nanometer plating layer into the substrate; removing the performing substrate away from the substrate to expose the circuit metal layer; forming at least one through hole on the other surface of the substrate with respect to the circuit metal layer to generate at least one opening exposing part of the nanometer plating layer; forming the second metal layer on the substrate to at least fill up the at least one opening; pattering the second metal layer to form the second circuit metal layer; forming the second nanometer plating layer on the circuit metal layer, and forming the third nanometer plating layer on the second circuit metal layer; and forming the cover layer made of the binder or the solder resist on the substrate for covering the surfaces of the substrate, the second nanometer plating layer and the third nanometer plating layer, wherein the surface of the performing substrate, and the outer surfaces of the circuit metal layer, the nanometer plating layer, the second circuit metal layer and the second nanometer plating layer have a roughness which is defined by Ra<0.35 μm and Rz<3 μm and not recognizable by cross-sectional examination through an optical microscope of 1,000 magnifications.

The method of the present invention improves the junction adhesion between the nanometer plating layer and cover layer by chemical bonding. Further, the side effect in the prior arts resulting from reserved circuit width for compensation by roughening the circuit metal layer is also resolved. Since the surface of the laminate circuit board manufactured by the present invention is smooth and no additional circuit width is necessarily reserved for compensation, the density of the circuit increases and the structure for the multilayer circuit of is accomplished by stacking

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic diagram to illustrate the laminate circuit board in the prior arts;

FIG. 2 shows a flow diagram to illustrate a method of manufacturing the laminate circuit board structure with the multilayer circuit structure according to the first embodiment of the present invention;

FIGS. 3A to 3H show cross-sectional diagrams to illustrate the method according to the first embodiment of the present invention;

FIG. 4 shows a flow diagram to illustrate a method according to the second embodiment of the present invention; and

FIGS. 5A to 5K show cross-sectional diagrams to illustrate the method according to the second embodiment of the present invention.

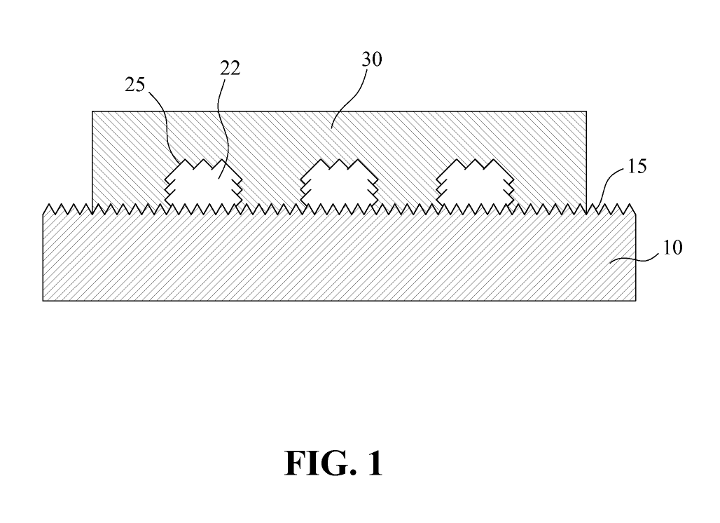

### DETAILED DESCRIPTION OF THE PREFERRED EMBODIMENT

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

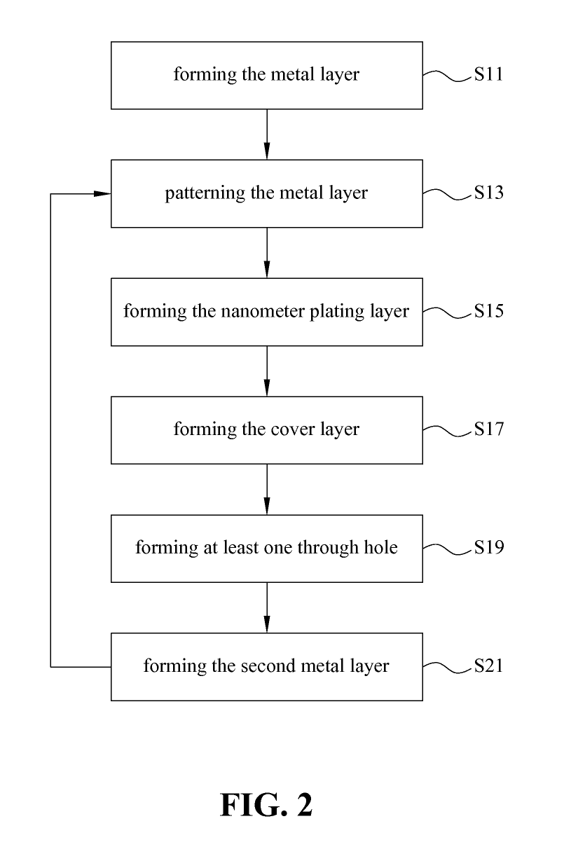

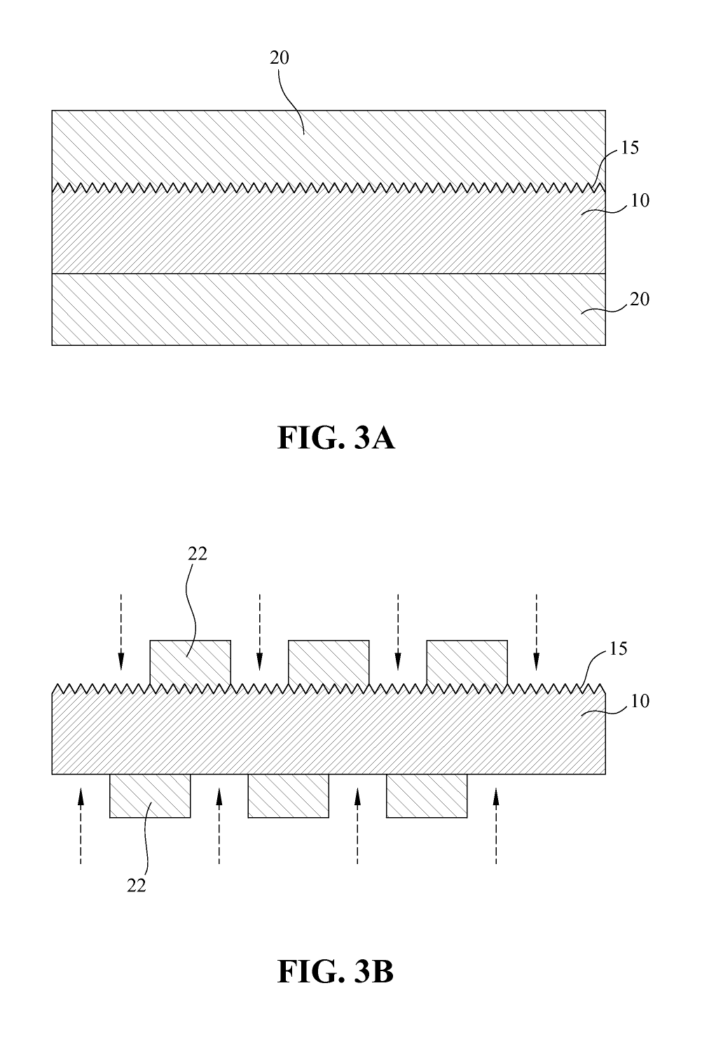

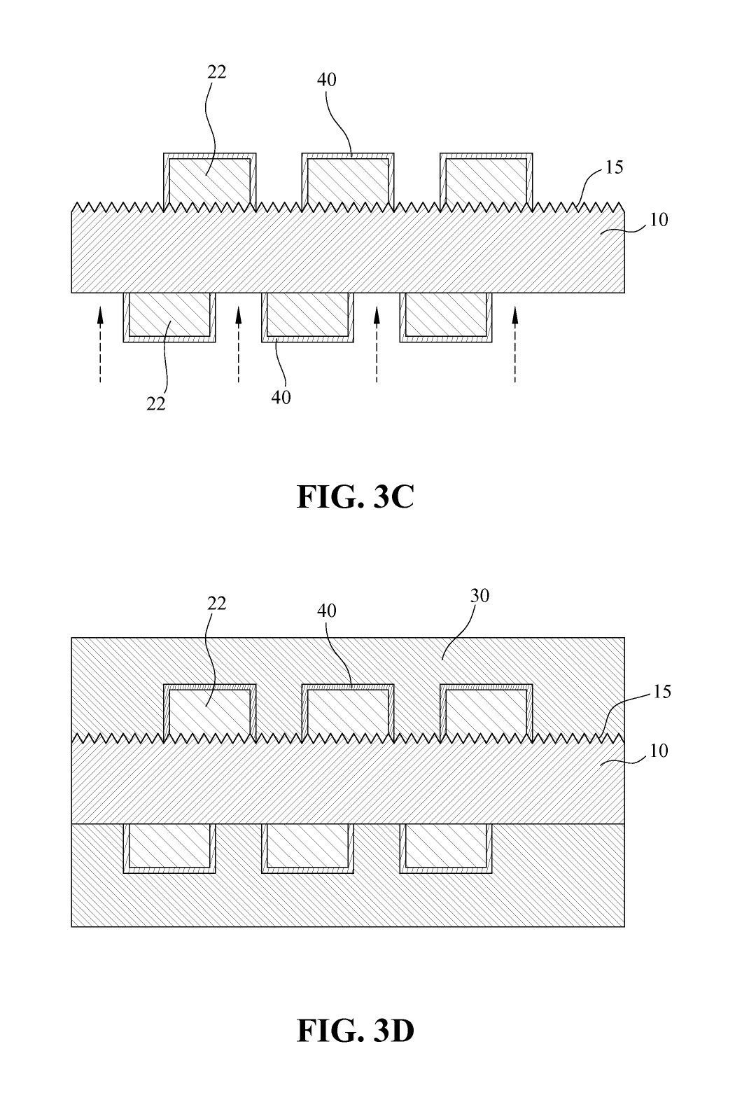

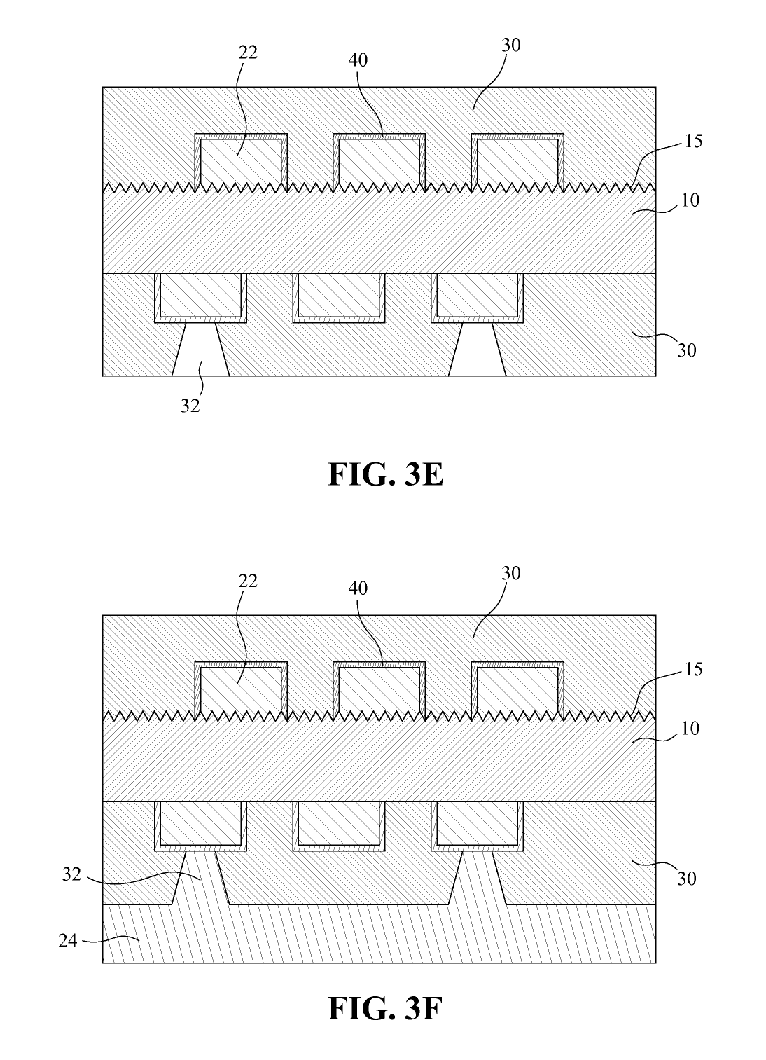

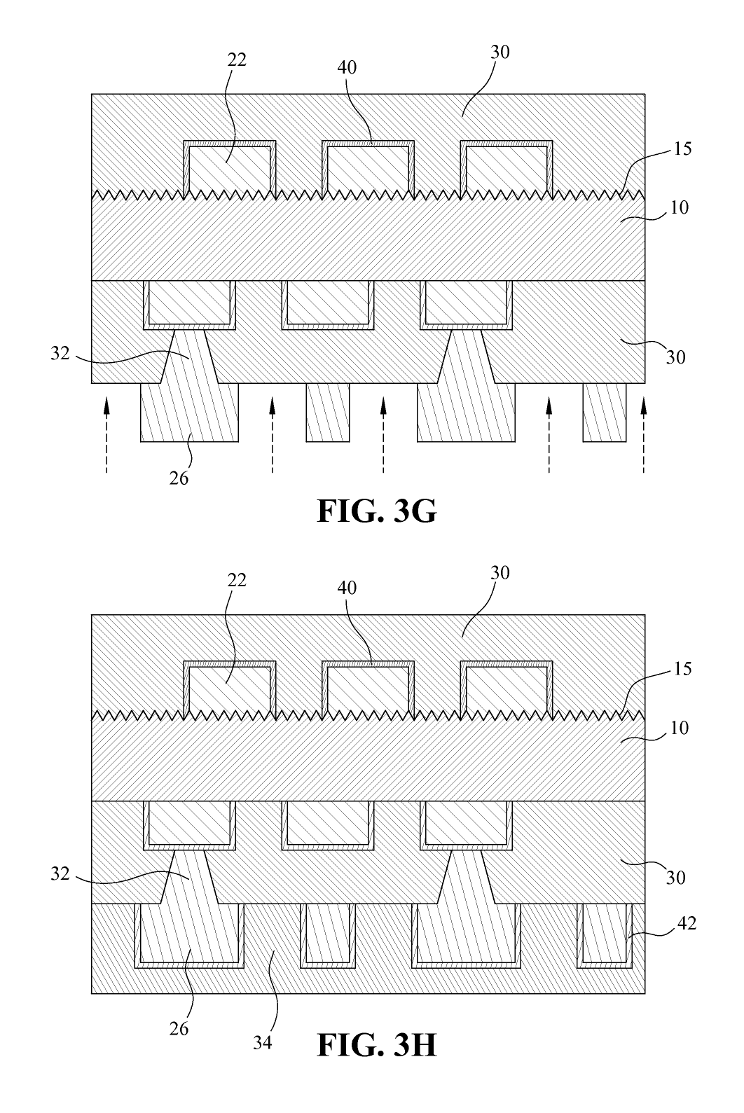

Please refer to FIG. 2 as the flow diagram to illustrate the method of manufacturing the laminate circuit board structure with the multilayer circuit structure according to the first embodiment of the present invention. The method according to the first embodiment comprises the steps S11, S13, S15, S17, S19 and S21, sequentially performed to manufacture the laminate circuit board structure with the multi-layer circuit structure. To clearly illustrate the characteristics of the present invention, FIGS. 3A to 3H showing the cross-sectional diagrams in the respective steps in the method of the present invention are preferredly referenced. Firstly, as shown in FIGS. 2 and 3A, the step S11 is performed by forming the metal layer 20 on at least one surface of the substrate 10 which is made of an insulation material, such as FR4 glass fiber or bismaleimide triazime resin (BT resin). Both the at least one surface of the substrate 10 and the outer surface of the metal layer 20 formed on the substrate 10 have a roughness which is defined by Ra<0.35 μm and Rz<3 μm and not recognizable by cross-sectional examination through an optical microscope of 1,000 magnifications. The circuit metal layer 20 is made of at least one of copper, aluminum, silver and gold, and can be formed through foil pressing, electric plating, electroless plating, evaporation or sputtering.

As shown in FIG. 3B, for the step S13, the metal layer 20 is patterned to form the circuit metal layer 22 through the traditional image transfer process, such as lithography, electric plating, wet etching, laser scribing or plasma etching. For the step S15 shown in FIGS. 2 and 3C, the nanometer plating layer 40 with a smooth outer surface having a thickness of 5˜40 nm is formed on the outer surface of the circuit metal layer 22 through electroless plating (chemical plating), evaporation, sputtering or atomic layer deposition (ALD). As an example for electroless plating, the circuit metal layer 22 is immersed in the chemical substitution solution to perform atomic substitution, and the chemical substitution solution comprises at least one of alkyleneglycol 30˜35 wt %, sulfuric acid 10˜30 wt %, thiourea 5˜10 wt % and tin compound 5 wt %. The nanometer plating layer 40 is made of at least two of copper, tin, aluminum, nickel, silver and gold.

As shown in FIG. 3D, the step S17 is performed to form the cover layer 30, which is made of a binder or a solder resist and covers the circuit metal layer 22 and the nanometer plating layer 40. With the method of the first embodiment of the present invention, the circuit metal layer 22 is formed as a structure with three smooth surfaces. The surfaces of the circuit metal layer 22 and the nanometer plating layer 40 do not have a recognizable roughness examined in cross-section through an optical microscope of 1,000 magnifications. In FIG. 3E, at least one through hole on the cover layer 40 with respect to the circuit metal layer 22 is formed through laser or mechanical drilling to generate at least one opening 32 exposing part of the nanometer plating layer 40 with respect to the step S19 shown in FIG. 2. For the step S21, the second metal layer 24 is formed on the cover layer 30 through electric plating, electroless plating, evaporation, sputtering or atomic layer deposition to at least fill up the at least one opening 32 as shown in FIG. 3F.

Then, refer to FIG. 3G. Repeat the step S13 to form the second circuit metal layer 26 by patterning the second metal layer 24. And finally, the steps S15 and S17 are sequentially repeated to form the second nanometer plating layer 42 on the second circuit metal layer 26, and the second cover layer 34 on the second nanometer plating layer 42, a stacked structure as shown in FIG. 3H. It should be noted that the example showing the stacked structure here is only exemplarily illustrative for reference, and not limitative.

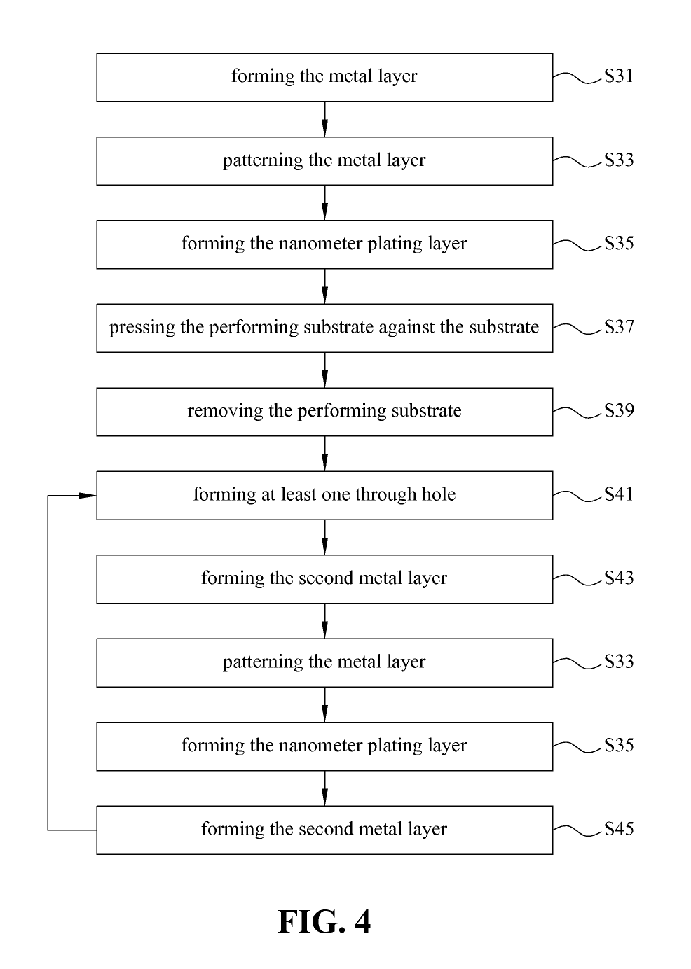

Please refer to FIG. 4 for the method according to the second embodiment of the present invention. The method of the second embodiment comprises the steps S31, S33, S35, S37, S39, S41, S43 and S45 to form the laminate circuit board with the multilayer circuit structure.

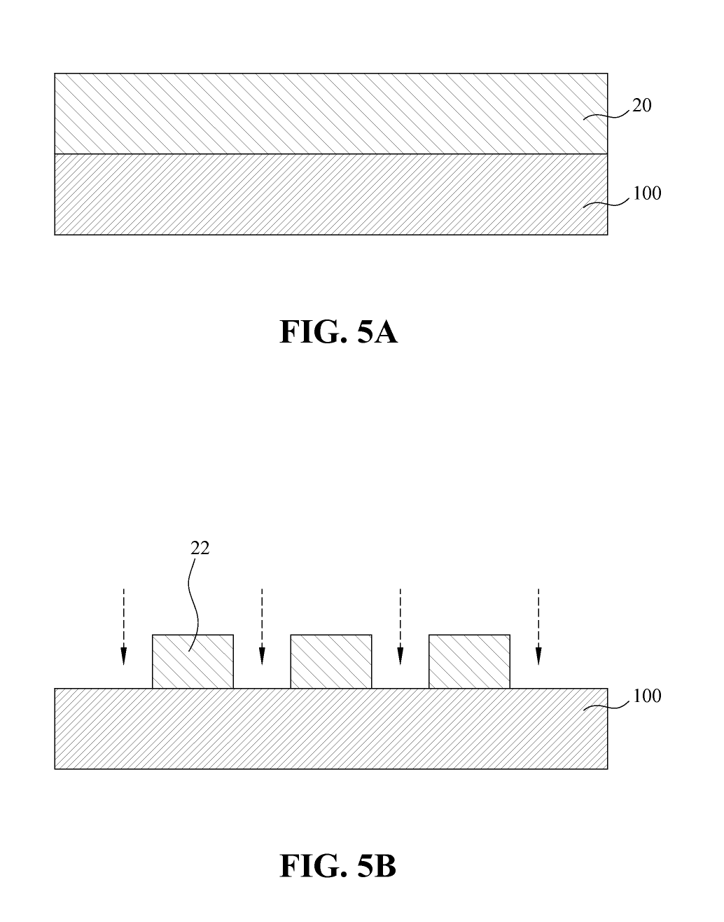

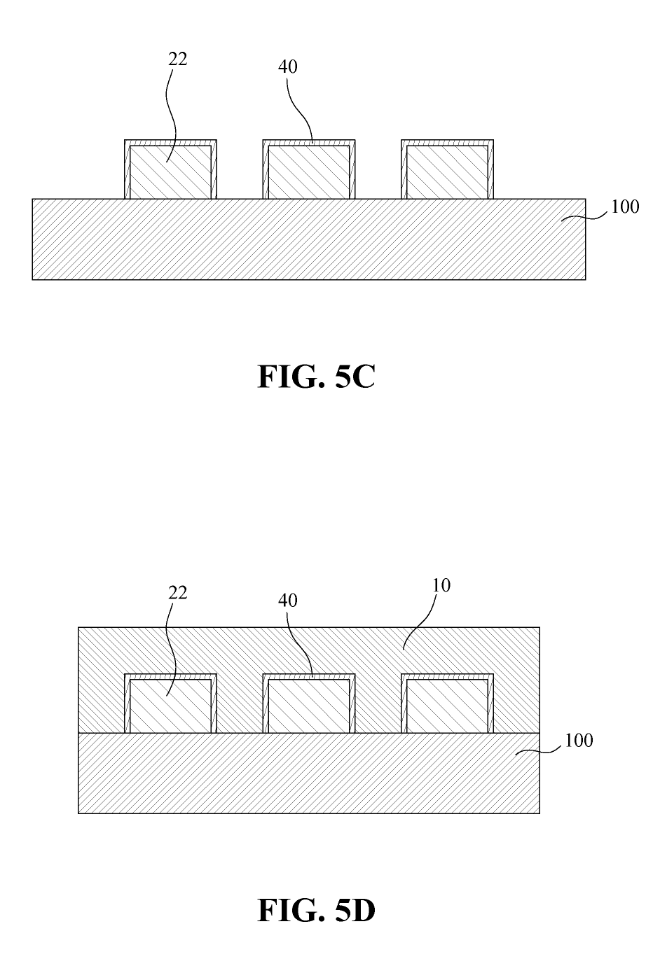

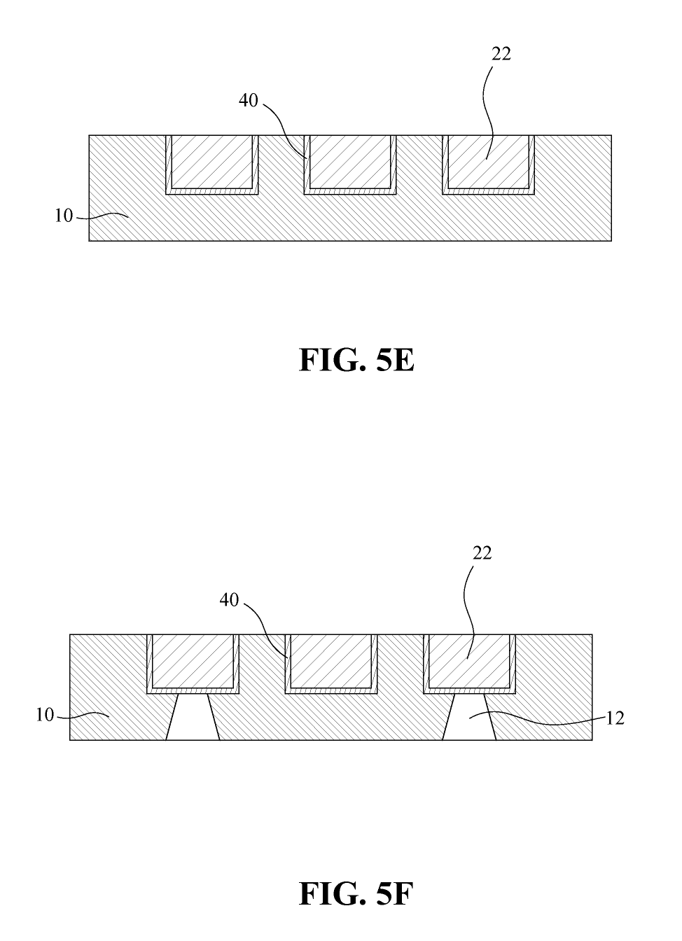

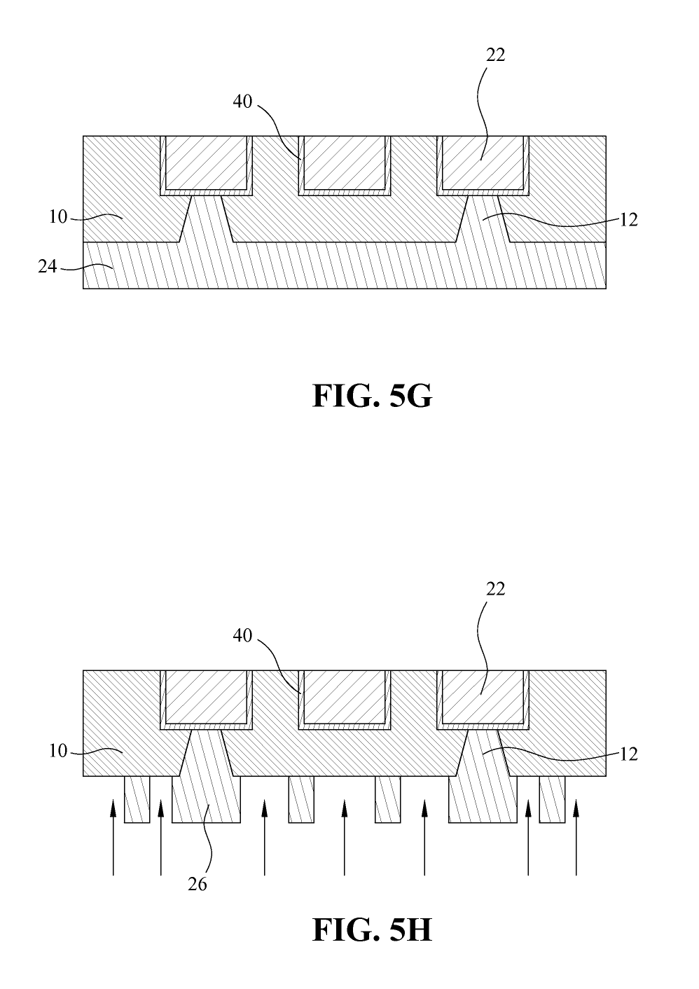

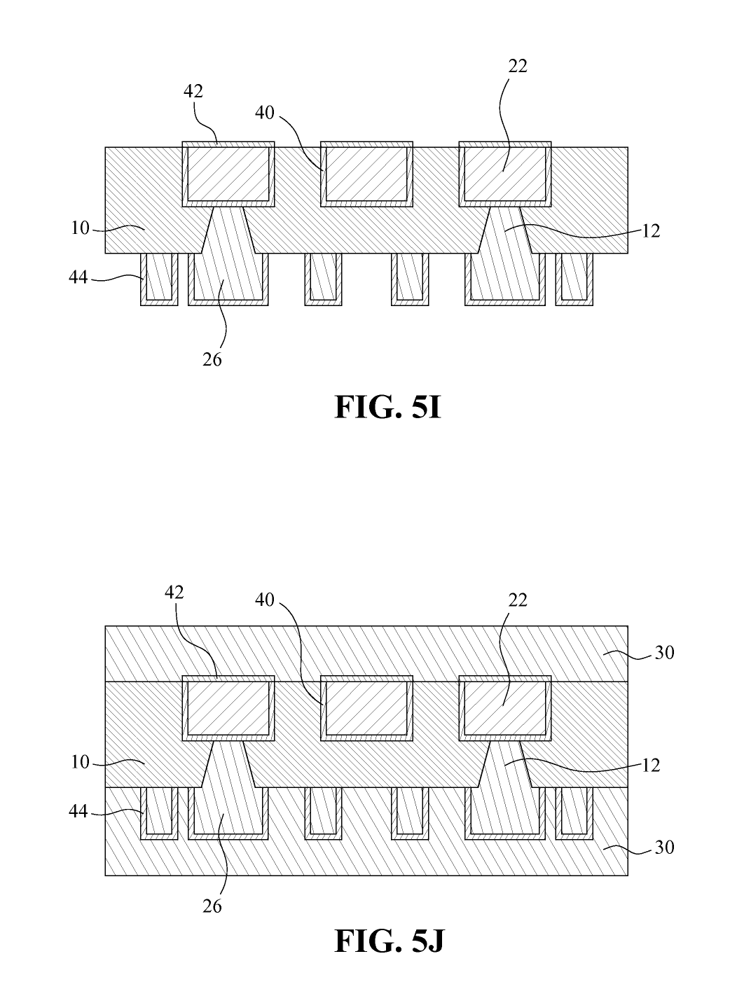

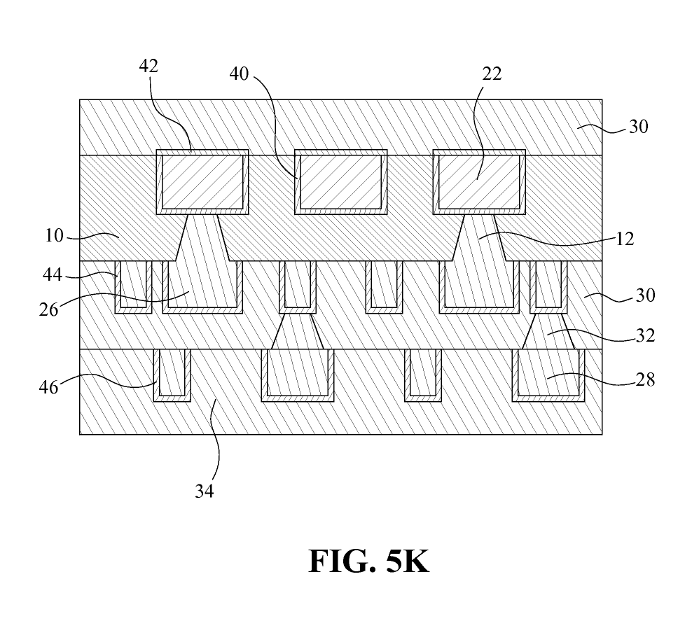

Further refer to FIGS. 5A to 5K for schematically showing the cross-sectional diagrams to illustrate the respective steps in the method according to the second embodiment of the present invention. First in FIG. 5A, the step 31 is performed by forming the metal layer 20 on the surface of the performing substrate 100, having a roughness which is defined by Ra<0.35 μm and Rz<3 μm and not recognizable by cross-sectional examination through an optical microscope of 1,000 magnifications. The performing substrate 100 is a single metal plate, a multiple metal plate or a composite plate. For example, the single metal plate is a polished steel plate or an aluminum plate, the multiple metal plate is a steel plate or an aluminum plate coated with a copper layer or an aluminum layer, and the composite plate is an FR4 glass fiber substrate coated with the copper layer or the aluminum layer, or a bismaleimide triazime resin substrate. It should be noted that the above examples are only illustrative and not limitative. For the step S33, the metal layer 20 is patterned to form the circuit metal layer 22 as shown in FIG. 5B through the image transfer process, such as lithography, electric plating, wet etching, laser scribing or plasma etching.

In the FIG. 5C, the step S35 similar to the first embodiment is performed by forming the nanometer plating layer 40 with a thickness of 5˜40 nm on the circuit metal layer 22. As shown in FIG. 5D, the step S37 is to press the performing substrate 100 against the substrate 10 to push the circuit metal layer 22 and the nanometer plating layer 40 into the substrate 10 such that the circuit metal layer 22 and the nanometer plating layer 40 are embedded in the substrate 10. The surface of the performing substrate 100, the outer surfaces of the circuit metal layer 22 and the nanometer plating layer 40 are smooth and have a roughness which is defined by Ra<0.35 μm and Rz<3 μm and not recognizable by cross-sectional examination through an optical microscope of 1,000 magnifications.

In FIG. 5E, the step S29 is performed by removing the performing substrate 100 away from the substrate 10 to expose the outer surface of the circuit metal layer 22.

Then, the step S41 as shown in FIG. 5F is to form at least one through hole in the substrate 10 with respect to the circuit metal layer 22 to generate at least one opening 12 exposing part of the nanometer plating layer 40. For the step S43, the second metal layer 24 is formed on the substrate 10 as shown in FIG. 5G to at least fill up the at least one opening 12 by electric plating, electroless plating, evaporation, sputtering or atomic layer deposition.

As shown in FIG. 5H, the step S33 are repeated to form the second circuit metal layer 26 by patterning the second metal layer 24. In FIG. 5I, the step S35 is then repeated to form the second nanometer plating layer 42 on the circuit metal layer 22 and the third nanometer plating layer 44 on the second circuit metal layer 26.

Next, refer to FIG. 5J. The step S45 is performed to form the cover layer 30 made of the binder or the solder resist on the substrate 10 for covering the exposed surfaces of the substrate 10, the second nanometer plating layer 42 and the third nanometer plating layer 44. Optionally, the above-mentioned steps S41, S43, S33, S35 and S45 are repeated to sequentially form the at least one opening 32, the third circuit metal layer 28, the fourth nanometer plating layer 46 and the second cover layer 34, wherein the at least one opening 32 formed in the cover layer 30 is filled with the third circuit metal layer 28, the fourth nanometer plating layer 46 is on the third circuit metal layer 28, and the second cover layer 34 is used to cover the fourth nanometer plating layer 46. Thus, a stacked structure with multilayer circuit is formed. It should be noted that the number of the layers in the stacked structure are optional and not limited to the example illustrated here. That is, the steps S41, S43, S33, S35 and S45 can be repeated at least one time.

One feature of the method according to the present invention is to improve the junction adhesion by the chemical bonding between the nanometer plating layer 40 and the cover layer 30 or the substrate 10. It does not need to roughen the surface of the circuit metal layer 20 for compensation of the circuit width and no reserved circuit width is required. Therefore, the side effect resulting from the reserved circuit width is eliminated because of the smooth surface of the laminate circuit board with the multi-layer circuit structure manufactured by the method according to the present invention such that much more dense circuit can be implemented in the substrate with the same area to form the multi-layer circuit structure.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method of manufacturing a laminate circuit board with a multilayer circuit structure, comprising:
forming a metal layer on both an up side and a down side of a substrate;
patterning the metal layer to form a circuit metal layer through an image transfer process;
forming a nanometer plating layer with a thickness of 5˜40 nm on the circuit metal layer; and
forming a cover layer made of a binder or a solder resist on the substrate for covering the circuit metal layer and the nanometer plating layer to generate the multi-layer circuit structure,
wherein at least one of the up side and the down side of the substrate is a smooth surface, and an outer surface of the circuit metal layer, the smooth surface of the substrate and an outer surface of the nanometer plating layer have a roughness which is defined by Ra (Arithmetical mean roughness)<0.35 μm and Rz (Ten-point mean roughness)<3 μm and not recognizable by cross-sectional examination through an optical microscope of 1,000 magnifications.

2. The method as claimed in claim 1, further comprising:
forming at least one through hole on the cover layer with respect to the circuit metal layer to generate at least one opening exposing part of the nanometer plating layer; and
forming a second metal layer on the cover layer to at least fill up said at least one opening, and repeating all above steps.

3. The method as claimed in claim 1, wherein said substrate is made of FR4 glass fiber or bismaleimide triazime resin, said metal layer is made of at least one of copper, aluminum, silver and gold, and said nanometer plating layer is made of at least two of copper, tin, aluminum, nickel, silver and gold.

4. The method as claimed in claim 1, wherein said nanometer plating layer is formed by electroless plating, evaporation, sputtering or atomic layer deposition.

5. The method as claimed in claim 4, wherein said nanometer plating layer is formed by the electroless plating through immersing the circuit metal layer into a chemical substitution solution to perform atomic substitution, and said chemical substitution solution comprises at least one of alkyleneglycol 30˜35 wt %, sulfuric acid 10˜30 wt %, thiourea 5˜10 wt % and tin compound 5 wt %.

6. A method of manufacturing a laminate circuit board with a multilayer circuit structure, comprising steps of:
forming a metal layer on at least one surface of a substrate, said at least one surface of the substrate being a smooth surface;
patterning the metal layer to form a circuit metal layer through an image transfer process;
forming a nanometer plating layer with a thickness of 5˜40 nm on the circuit metal layer;
forming a cover layer made of a binder or a solder resist on the substrate for covering the circuit metal layer and the nanometer plating layer;
forming at least one through hole on the cover layer with respect to the circuit metal layer to generate at least one opening exposing part of the nanometer plating layer;
forming a next metal layer on the cover layer to at least fill up said at least one opening; and
repeating part of above steps by patterning said next metal layer, forming a next nanometer plating layer, and forming a next cover layer to generate the multilayer circuit structure in the laminate circuit board,
wherein an outer surface of the circuit metal layer, the smooth surface of the substrate and an outer surface of the nanometer plating layer have a roughness which is defined by Ra<0.3 μm and Rz<3 μm and not recognizable by cross-sectional examination through an optical microscope of 1,000 magnifications.

7. The method as claimed in claim 6, wherein said substrate is made of FR4 glass fiber or bismaleimide triazime resin, said metal layer is made of at least one of copper, aluminum, silver and gold, and said nanometer plating layer is made of at least two of copper, tin, aluminum, nickel, silver and gold.

8. The method as claimed in claim 6, wherein said nanometer plating layer is formed by electroless plating, evaporation, sputtering or atomic layer deposition.

9. The method as claimed in claim 8, wherein said nanometer plating layer is formed by the electroless plating through immersing the circuit metal layer into a chemical substitution solution to perform atomic substitution, and said chemical substitution solution comprises at least one of alkyleneglycol 30˜35 wt %, sulfuric acid 10˜30 wt %, thiourea 5˜10 wt % and tin compound 5 wt %.

10. A method of manufacturing a laminate circuit board with a multilayer circuit structure, comprising:
forming a metal layer on a performing substrate;
patterning the metal layer to form a circuit metal layer through an image transfer process;
forming a nanometer plating layer with a thickness of 5˜40 nm on the circuit metal layer;
pressing the performing substrate against a substrate to push the circuit metal layer and the nanometer plating layer into the substrate;
removing said performing substrate away from the substrate to expose the circuit metal layer;
forming at least one through hole on the substrate with respect to the circuit metal layer to generate at least one opening exposing part of the nanometer plating layer;
forming a second metal layer on the substrate to at least fill up said at least one opening;
pattering the second metal layer to form a second circuit metal layer;
forming a second nanometer plating layer on the circuit metal layer, and forming a third nanometer plating layer on the second circuit metal layer; and
forming a cover layer made of a binder or a solder resist on the substrate for covering a surface of the substrate, the second circuit metal layer and the second nanometer plating layer to generate the multilayer circuit structure in the laminate circuit board,
wherein a surface of the performing substrate, and outer surfaces of the circuit metal layer, the nanometer plating layer, the second circuit metal layer and the second nanometer plating layer have a roughness which is defined by Ra (Arithmetical mean roughness)<0.35 μm and Rz (Ten-point mean roughness)<3 μm and not recognizable by cross-sectional examination through an optical microscope of 1,000 magnifications.

11. The method as claimed in claim 10, further repeating part of above steps at least one time by forming at least one through hole in the cover layer, forming a next metal layer, pattering the next metal layer, forming a next nanometer plating layer and forming a next cover layer.

12. The method as claimed in claim 10, wherein said metal layer is made of at least one of copper, aluminum, silver and gold, said nanometer plating layer is made of at least two of copper, tin, aluminum, nickel, silver and gold, and said performing substrate is a single metal plate, a multiple metal plate or a composite plate.

13. The method as claimed in claim 12, wherein said single metal plate is a polished steel or aluminum plate, said multiple metal platen is a steel or aluminum plate coated with a copper layer or an aluminum layer, and said composite plate is an FR4 glass fiber substrate coated with the copper layer or the aluminum layer, or a bismaleimide triazime resin substrate.

14. The method as claimed in claim 10, wherein said nanometer plating layer, said second nanometer plating layer and said third nanometer plating layer are formed by electroless plating, evaporation, sputtering or atomic layer deposition.

15. The method as claimed in claim 14, wherein said nanometer plating layer is formed by the electroless plating through immersing the circuit metal layer into a chemical substitution solution to perform atomic substitution, and said chemical substitution solution comprises at least one of alkyleneglycol 30˜35 wt %, sulfuric acid 10˜30 wt %, thiourea 5˜10 wt % and tin compound 5 wt %.
